(19) United States
(12) Patent Application Publication
(10) Pub. No.: US 2025/0285567 A1
(43) Pub. Date: Sep. 11, 2025

(54) DISPLAY DEVICE AND METHOD OF DRIVING DISPLAY DEVICE

(71) Applicant: SAMSUNG DISPLAY CO., LTD., YONGIN-SI (KR)

(72) Inventors: Seok Hoon YOON, Yongin-si (KR); Jae Mo CHUNG, Yongin-si (KR); Jong Heon HAN, Yongin-si (KR)

(21) Appl. No.: 18/949,146

(22) Filed: Nov. 15, 2024

(30) Foreign Application Priority Data
Mar. 5, 2024 (KR) 10-2024-0031475

(51) Int. Cl. G09G 3/00; G01R 31/28

(52) U.S. Cl. CPC G09G 3/006; G01R 31/2831

(57) ABSTRACT

A display device includes a display panel including a plurality of pixels, a first conductive ball connected to the display panel, and a driving integrated circuit connected to the first conductive ball and configured to generate and output a first gate driver control signal to the display panel through the first conductive ball, receive a first return signal of the first gate driver control signal from the display panel, wherein the first return signal corresponds to the first gate drive control signal provided to the display panel through the first conductive ball, and perform a first waveform comparing operation in which a waveform of the first gate driver control signal is compared with a waveform of the first return signal to determine whether the first conductive ball is oxidized.

### CROSS-REFERENCE TO RELATED APPLICATION

The present application claims priority under 35 U.S.C. § 119 (a) to Korean patent application No. 10-2024-0031475 filed on Mar. 5, 2024 in the Korean Intellectual Property Office, the entire disclosure of which is herein incorporated by reference.

### BACKGROUND

### 1. Technical Field

The present disclosure relates to a display device and a method of driving a display device.

### 2. Related Art

A driving integrated circuit for driving a display panel may be electrically coupled to the display panel through conductive balls. The driving integrated circuit may supply control signals to the display panel via the conductive balls. Oxidation occurring in the conductive balls due to driving for a long time may cause an increase in resistance, a disconnection, a short circuit, a bonding failure, and the like, and change waveforms of the control signals. In addition, this may result in deterioration of the reliability of a display device.

The above information disclosed in this Related Art section is only for enhancement of understanding of the background of the disclosure and therefore it may contain information that does not form the prior art that is already known to a person of ordinary skill in the art.

### SUMMARY

Embodiments provide a display device and a method of driving a display device, in which oxidation of conductive balls is minimized, thereby improving the reliability of the display device.

According to an aspect of the present disclosure, a display device includes a display panel including a plurality of pixels, a first conductive ball connected to the display panel, and a driving integrated circuit connected to the first conductive ball and configured to generate and output a first gate driver control signal to the display panel through the first conductive ball, receive a first return signal of the first gate driver control signal from the display panel, wherein the first return signal corresponds to the first gate drive control signal provided to the display panel through the first conductive ball, and perform a first waveform comparing operation in which a waveform of the first gate driver control signal is compared with a waveform of the first return signal to determine whether the first conductive ball is oxidized.

The display panel includes a first gate driver configured to supply a plurality of first gate signals to corresponding first pixels of the plurality of pixels, a first panel input pad connected to the first conductive ball and receiving the first gate driver control signal from the driving integrated circuit through the first conductive ball, a first switch selectively connecting the first panel input pad to the first gate driver in response to a first switch control signal of the driving integrated circuit, and a first test pad connected to an output of the first switch and the driving integrated circuit, wherein the first return signal is transferred to the driving integrated circuit through the first test pad.

The display device further includes a second conductive ball electrically connecting the driving integrated circuit to the display panel. The driving integrated circuit is configured further to generate and output a second gate driver control signal to the display panel through the second conductive ball, and receive a second return signal of the second gate driver control signal from the display panel, wherein the second return signal corresponds to the second gate drive control signal provided to the display panel through the second conductive ball, perform a second waveform comparing operation in which a waveform of the second gate driver control signal is compared with a waveform of the second return signal to determine whether the second conductive ball is oxidized.

The display panel further includes a second gate driver spaced apart from the first gate driver in a first direction, the second gate driver supplying a plurality of second gate signals of the plurality of gate signals to corresponding second pixels of the plurality of pixels, a second panel input pad receiving the second gate driver control signal from the driving integrated circuit through the second conductive ball, a second switch selectively connecting the second panel input pad to the second gate driver in response to a second switch control signal of the driving integrated circuit, and a second test pad connected to an output of the second switch and the driving integrated circuit, wherein the second return signal is transferred to the driving integrated circuit through the second test pad.

The driving integrated circuit is configured to perform the first waveform comparing operation and the second waveform comparing operation in a first period and in a second period different from the first period.

The first gate driver control signal and the second gate driver control signal are substantially the same.

The driving integrated circuit includes a timing controller circuit configured to generate the first gate driver control signal, a first return input pad connected to the first test pad of the display panel and receiving the first return signal from the first test pad of the display panel, and a waveform comparator circuit configured to compare the waveform of the first gate driver control signal with the waveform of the first return signal, and compare the waveform of the second gate driver control signal with the waveform of the second return signal.

The driving integrated circuit further includes a control signal generator circuit configured to receive a waveform comparison result transferred from the waveform comparator circuit, determine whether the first conductive ball is oxidized based on the waveform comparison result, and in response to determination of the first conductive ball being oxidized, turn off the first switch and supply a reverse bias voltage to the first conductive ball.

The driving integrated circuit further includes an output pad unit including a plurality of output pads. The output pad unit is connected to the control signal generator circuit, the first conductive ball, and the first switch. The control signal generator circuit is configured to supply the first switch control signal to the first switch through a corresponding output pad of the output pad unit.

The reverse bias voltage is a voltage level at which the first conductive ball is reduced.

According to an aspect of the present disclosure, a method of driving a display device including a display panel and a first conductive ball electrically connected to the display panel, the method includes generating and outputting a first gate driver control signal to the display panel through the first conductive ball, receiving a first return signal of the first gate driver control signal from the display panel, wherein the first return signal corresponds to the first gate drive control signal provided to the display panel through the first conductive ball, and performing a first waveform comparing operation in which a waveform of the first gate driver control signal is compared with a waveform of the first return signal to determine whether the first conductive ball is oxidized.

The receiving of the first return signal of the first gate driver control signal from the display panel includes transferring the first return signal to a driving integrated circuit through a first switch and a first test pad of the display panel.

The display device further includes a second conductive ball electrically connected to the display panel. The method further includes generating and outputting a second gate driver control signal to the display panel through the second conductive ball, and receiving a second return signal of the second gate driver control signal from the display panel, wherein the second return signal corresponds to the second gate drive control signal provided to the display panel through the second conductive ball, and performing a second waveform comparing operation in which a waveform of the second gate driver control signal is compared with a waveform of the second return signal to determine whether the second conductive ball is oxidized.

The receiving of the second return signal of the second gate driver control signal from the display panel includes transferring the second return signal to the driving integrated circuit through a second switch and a second test pad of the display panel.

The first gate driver control signal and the second gate driver control signal are substantially the same.

The method further includes reducing the first conductive ball at a first period, and reducing the second conductive ball at a second period different from the first period.

The reducing of the first conductive ball includes determining whether the first conductive ball is oxidized based on a waveform comparison result of the performing of the first waveform comparing operation, and in response to determination of the first conductive ball being oxidized, turning off the first switch and supplying a first revers bias voltage to the first conductive ball so that the first conductive ball is reduced in the first period. The reducing of the second conductive ball includes determining whether the second conductive ball is oxidized based on a waveform comparison result of the performing of the second waveform comparing operation, and in response to determination of the second conductive ball being oxidized, turning off the second switch and supplying a second revers bias voltage to the second conductive ball so that the second conductive ball is reduced in the second period.

The first reverse bias voltage is a voltage level at which the first conductive ball is reduced. The first reverse bias voltage and the second reverse bias voltage have the same voltage level.

According to an aspect of the present disclosure, a display device includes a display panel including a plurality of pixels, a first conductive ball connected to the display panel, and a display driving device connected to the first conductive ball and configured to supply a first gate driver control signal to the display panel through the first conductive ball, receive a first return signal of the first gate driver control signal from the display panel, wherein the first return signal corresponds to the first gate drive control signal provided to the display panel through the first conductive ball, and perform a first waveform comparing operation in which a waveform of the first gate driver control signal is compared with a waveform of the first return signal, determine whether the first conductive ball is oxidized based on a waveform comparison result of the first waveform comparing operation, and supply a revers bias voltage to the first conductive ball in response to the determination of the first conductive ball is oxidized.

The reverse bias voltage is a voltage level at which the first conductive ball is reduced.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic block diagram illustrating a display device in accordance with embodiments of the present disclosure.

FIG. 2 is a schematic block diagram illustrating a driving integrated circuit shown in FIG. 1 in accordance with embodiments of the present disclosure.

FIG. 3 is a diagram illustrating an embodiment of the driving integrated circuit shown in FIG. 2 in accordance with embodiments of the present disclosure.

FIG. 4 is a diagram illustrating a reverse bias voltage shown in FIG. 3 in accordance with embodiments of the present disclosure.

FIGS. 5 to 8 are schematic diagrams illustrating an embodiment of the display device shown in FIG. 1 in accordance with embodiments of the present disclosure.

FIG. 9 is a flowchart illustrating a method of driving the display device shown in FIG. 1 in accordance with embodiments of the present disclosure.

FIG. 10 is a block diagram illustrating an electronic device in accordance with embodiments of the present disclosure.

FIG. 11 is a diagram illustrating an example in which the electronic device shown in FIG. 10 is implemented as a smartphone in accordance with embodiments of the present disclosure.

### DETAILED DESCRIPTION

Hereinafter, embodiments of the present disclosure will be described in more detail with reference to the accompanying drawings. In the description below, only a necessary part to understand an operation according to the present disclosure is described and the descriptions of other parts are omitted in order not to unnecessarily obscure subject matters of the present disclosure. In addition, the present disclosure is not limited to exemplary embodiments described herein, but may be embodied in various different forms. Rather, exemplary embodiments described herein are provided to thoroughly and completely describe the disclosed contents and to sufficiently transfer the ideas of the disclosure to a person of ordinary skill in the art.

In the entire specification, when an element is referred to as being “connected” or “coupled” to another element, it can be directly connected or coupled to another element or be indirectly connected or coupled to another element with one or more intervening elements interposed therebetween. The technical terms used herein are used only for the purpose of illustrating a specific embodiment and not intended to limit the embodiment. It will be understood that when a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the present disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the present disclosure, so that changes in a shape as shown due to, for example, manufacturing technology and/or a tolerance may be expected. Therefore, the embodiments of the present disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

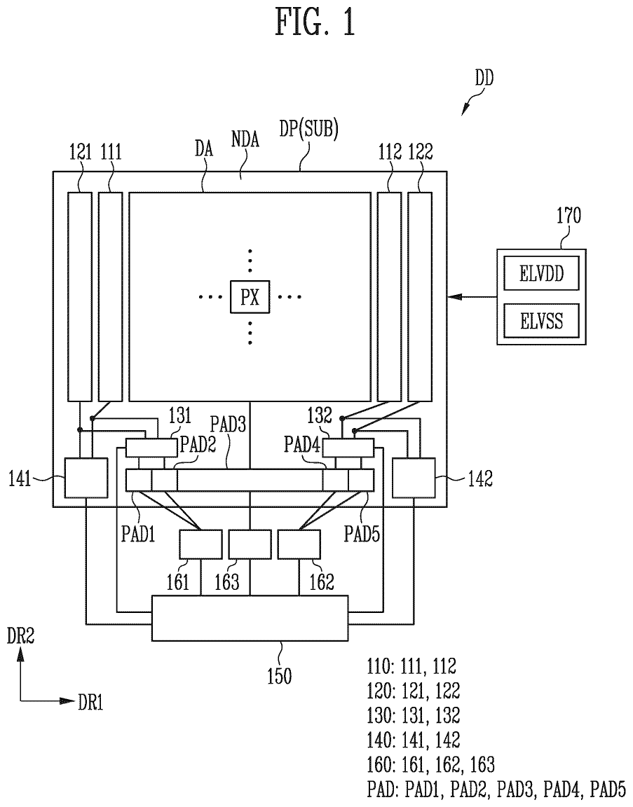

FIG. 1 is a schematic block diagram illustrating a display device in accordance with embodiments of the present disclosure.

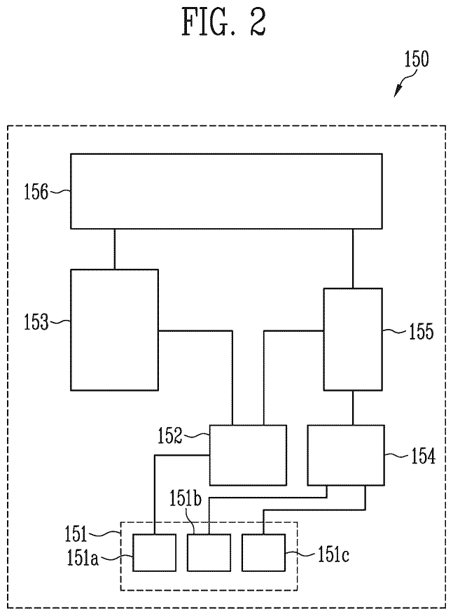

Referring to FIG. 1, the display device DD may include a display panel DP, a driving integrated circuit 150, conductive balls 160, and a power supply 170. The display panel DP may include a substrate SUB, gate drivers 110, emission drivers 120, switches 130, test pads 140, and pads PAD. For the convenience of a description, a display driver device is referred as the driving integrated circuit 150. The display driver device may be implemented as a single integrated circuit on the same semiconductor chip. For example, various functional blocks of FIG. 2 may be implemented in a single integrated circuit on the same semiconductor chip. However, the present disclosure is not limited thereto. In an embodiment, a display driver device includes at least two different semiconductor chips mounted on a substrate such as a printed circuit board. The various functional blocks may be implemented in the at least two different semiconductor chips.

The substrate SUB (or the display panel DP) may include a display area DA in which an image is displayed and a non-display area NDA at the periphery of the display area DA (e.g., an edge area of the display area DA). A plurality of pixels PX may be disposed in the display area DA of the display panel DP. The gate drivers 110, the emission drivers 120, the switches 130, the test pads PAD, and signal lines (e.g., gate lines (not shown), data lines (not shown), and emission control lines (not shown)) may be disposed in the non-display area NDA of the display panel DP.

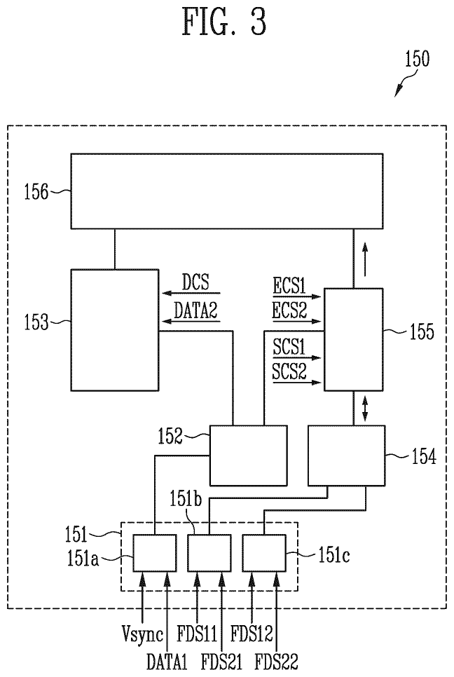

The gate drivers 110 may supply gate signals to the plurality of pixels PX through the gate lines. More specifically, the gate drivers 110 may generate gate signals, based on first and second gate driver control signals SCS1 and SCS2 (see FIG. 3), and provide the gate signals to the gate lines. The first and second gate driver control signals SCS1 and SCS2 may be supplied from the driving integrated circuit 150. In an embodiment, each of the first and second gate driver control signals SCS1 and SCS2 may be provided in a pulse form alternately having a first gate power voltage VGH (e.g., a voltage having a level of a positive value) and a second gate power voltage VGL (e.g., a voltage having a level of a negative value). In an embodiment, each of the first and second gate driver control signals SCS1 and SCS2 may be provided in a linear form having the first gate power voltage VGH. For example, each of the first and second gate driver control signals SCS1 and SCS2 may be provided at a constant voltage level of the first gate power voltage VGH. The first gate driver control signal SCS1 and the second gate driver control signal SCS2 may be substantially the same signal.

The gate drivers 110 may include a first gate driver 111 and a second gate driver 112. The first gate driver 111 and the second gate driver 112 may be spaced apart from each other in a first direction DR1. In an embodiment, odd-numbered gate lines may be connected to the first gate driver 111, and even-numbered gate lines may be connected to the second gate driver 112, and each of the odd-numbered gate lines and each of the even-numbered gate lines may be alternately arranged in the second direction DR2. The first gate driver 111 and the second gate driver 112 may alternately supply gate signals to the gate lines.

The emission drivers 210 may supply emission control signals to the plurality of pixels PX through the emission control lines. More specifically, the emission drivers 120 may generate emission control signals, based on first and second emission driver control signals ECS1 and ECS2 (see FIG. 3), and provide the emission control signals to the emission control lines. The first and second emission driver control signals ECS1 and ECS2 may be supplied from the driving integrated circuit 150. In an embodiment, each of the first and second emission driver control signals ECS1 and ECS2 may be provided in a pulse form having alternately having a first gate power voltage VGH (e.g., a voltage having a level of a positive value) and a second gate power voltage VGL (e.g., a voltage having a level of a negative value). In an embodiment, each of the first and second emission driver control signals ECS1 and ECS2 may be provided in a linear form having the first gate power voltage VGH. For example, each of the first and second emission driver control signals ECS1 and ECS2 may be provided at a constant voltage level of the first gate power voltage VGH. The first emission driver control signal ECS1 and the second emission driver control signal ECS2 may be substantially the same signal.

The emission drivers 120 may include a first emission driver 121 and a second emission driver 122. The first emission driver 121 and the second emission driver 122 may be spaced apart from each other in the first direction DR1.

In some embodiments, the gate drivers 110 and the emission drivers 120 may be integrated with the pixels PX to be formed in the display panel DP. However, embodiments of the present disclosure are not limited thereto. For example, the gate drivers 110 may be implemented as a separate integrated circuit distinguished from the display panel DP, and be mounted in the driving integrated circuit 150. In FIG. 1, it is illustrated that the gate drivers 110 are disposed in the non-display area NDA. However, embodiments of the present disclosure are not limited thereto. For example, the gate drivers 110 may be distributedly disposed in the display area DA (e.g., between pixels PX).

The driving integrated circuit 150 may include a data driver 153 (see FIG. 2). The data driver 153 may be connected to the data lines through a third data pad PAD3. The data driver 153 may supply data signals to the plurality of pixels PX through the data lines.

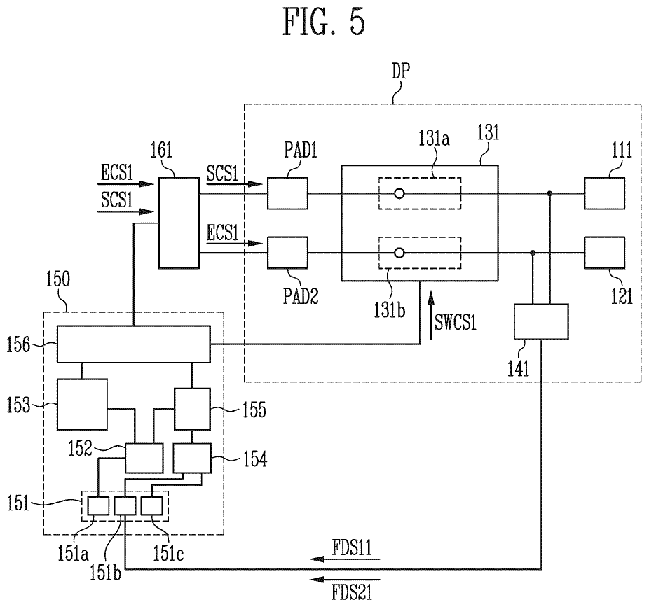

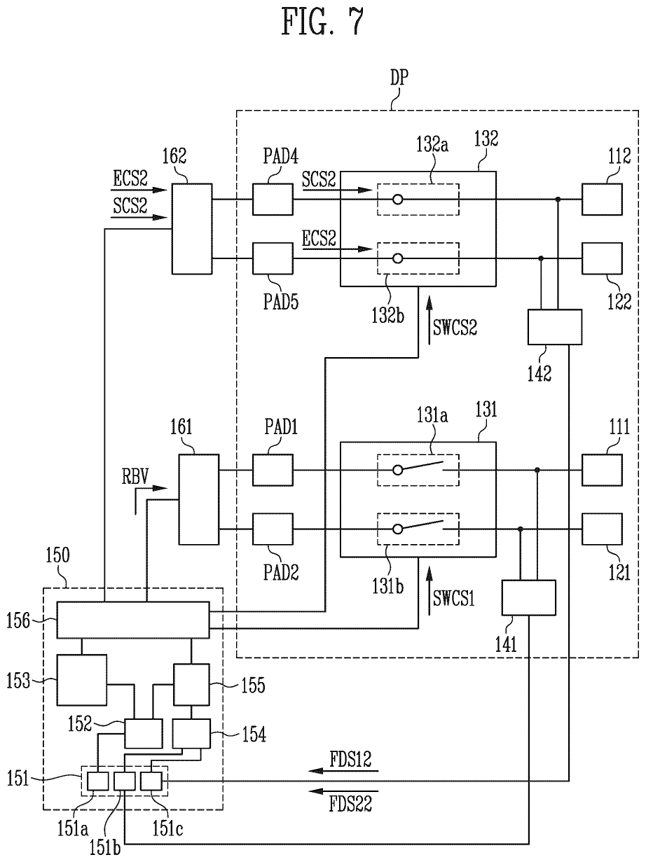

The switches 130 may include a first switch 131 and a second switch 132. The first switch 131 may include a 1ath switch 131a (see FIG. 5) and a 1bth switch 131b (see FIG. 5). The second switch 132 may include a 2ath switch 132a (see FIG. 7) and a 2bth switch 132b (see FIG. 7).

The first switch 131 and the second switch 132 may be spaced apart from each other in the first direction DR1. Each of the first switch 131 and the second switch 132 may be turned on or turned off by the driving integrated circuit 150.

When the first switch 131 is turned on, the first switch 131 may connect a first pad PAD1 to the first gate driver 111, and connect a second pad PAD2 (i.e., a first panel input pad) to the first emission driver 121. When the first switch 131 is turned off, the first switch 131 may block the connection between the first pad PAD1 and the first gate driver 111, and block the connection between the second pad PAD2 and the first emission driver 121.

When the second switch 132 is turned on, the second switch 132 may connect a fourth pad PAD4 (i.e., a second panel input pad) to the second gate driver 112, and connect a fifth pad PAD5 to the second emission driver 122. When the second switch 132 is turned off, the second switch 132 may block the connection between the fourth pad PAD4 and the second gate driver 112, and block the connection between the fifth pad PAD5 and the second emission driver 122. A configuration and an operation of the switches 130 will be described in detail later with reference to FIGS. 5 to 7.

The test pads 140 may include a first test pad 141 and a second test pad 142. The first test pad 141 and the second test pad 142 may be spaced apart from each other in the first direction DR1.

As shown in FIG. 1, each of the first gate driver 111 and the first emission driver 121 may be connected to the driving integrated circuit 150 through the first test pad 141. The first test pad 141 may detect the first gate driver control signal SCS1 passing through the first switch 131, and transfer the first gate driver control signal SCS1 in the form of an eleventh feedback signal FDS11 (i.e., a first return signal of the first gate driver control signal SCS1) (see FIG. 3) to the driving integrated circuit 150. In an embodiment, the first gate driver control signal SCS1 passing through the first switch 131 may be transferred to the driving integrated circuit 150 in the form of the eleventh feedback signal FDS11 (see FIG. 3). In other words, the first gate driver control signal SCS1 supplied from the driving integrated circuit 150 may return to the driving integrated circuit 150 through the first switch 131 and the first test pad 141. Also, the first test pad 141 may detect the first emission driver control signal ECS1, and transfer the first emission driver control signal ECS1 in the form of a twenty-first feedback signal FDS21 (see FIG. 3) to the driving integrated circuit 150. In an embodiment, the first emission driver control signal ECS1 passing through the first switch 131 may be transferred to the driving integrated circuit 150 in the form of the twenty-first feedback signal FDS21 (see FIG. 3). In other words, the first emission driver control signal ECS1 supplied from the driving integrated circuit 150 may return to the driving integrated circuit 150 through the first switch 131 and the first test pad 141.

As shown in FIG. 1, each of the second gate driver 112 and the second emission driver 122 may be connected to the driving integrated circuit 150 through the second test pad 142. The second test pad 142 may detect the second gate driver control signal SCS2 passing through the second switch 132, and transfer the second gate driver control signal SCS2 in the form of a twelfth feedback signal FDS12 (i.e., a second return signal of the second gate drive control signal SCS2) (see FIG. 3) to the driving integrated circuit 150. Also, the second test pad 142 may detect the second emission driver control signal ECS2, and transfer the second emission driver control signal ECS2 in the form of a twenty-second feedback signal FDS22 (see FIG. 3) to the driving integrated circuit 150.

The driving integrated circuit 150 may be electrically connected to the display panel DP through the conductive balls 160. The driving integrated circuit 150 may generate and output signals (e.g., the first gate driver control signal SCS1, the second gate driver control signal SCS2, the first emission driver control signal ECS1, the second emission driver control signal ECS2, and the like).

The driving integrated circuit 150 may sense oxidation of the conductive balls 160 by comparing a waveform of a signal output from the driving integrated circuit 150 with a waveform of a signal fed back and transferred to the driving integrated circuit 150. For example, the driving integrated circuit 150 may sense oxidation of a first conductive ball 161 by comparing a waveform of the first gate driver control signal SCS1 with a waveform of the eleventh feedback signal FDS11 fed back and transferred through the first test pad 141.

When the driving integrated circuit 150 senses the oxide of the conductive balls 160, a process of reducing the conductive balls 160 may be performed. A configuration of the driving integrated circuit 150 will be described in detail later with reference to FIG. 2. An operation of the driving integrated circuit 150 will be described in detail later with reference to FIGS. 5 to 7.

The conductive balls 160 may include the first conductive ball 161, a second conductive ball 162, and a third conductive ball 163. The conductive balls 160 may electrically connect the display panel DP and the driving integrated circuit 150 to each other. For example, the first conductive ball 161 may electrically connect each of the first and second pads PAD1 and PAD2 of the display panel DP to the driving integrated circuit 150. For example, the second conductive ball 162 may electrically connect the third pad PAD3 to the driving integrated circuit 150. The third conductive ball 163 may electrically connect each of the fourth and fifth pads PAD4 and PAD5 of the display panel DP to the driving integrated circuit 150.

Signals (e.g., the first gate driver control signal SCS1, the second gate driver control signal SCS2, and the like) output from the driving integrated circuit 150 may be supplied to the display panel DP via the conductive balls 160. In a process of receiving signals from the driving integrated circuit 150, the conductive balls 160 may lose electrons to the driving integrated circuit 150. For example, in a process of receiving signals having a voltage of a positive level from the driving integrated circuit 150, the conductive balls 160 may lose electrons to the driving integrated circuit 150. When such a phenomenon is repeated several times for a long time, the conductive balls 160 may be oxidized (or corroded).

When the conductive balls 160 are oxidized (or corroded), waveforms of the signals may be distorted while passing through the conductive balls 160. The signals of which the waveforms are distorted may be supplied to the display panel DP. In addition, as signals of which waveforms are unintentionally distorted are supplied to the display panel DP, the reliability of the display device may be deteriorated. The driving integrated circuit 150 senses oxidation of the conductive balls 160, and periodically reduces the conductive balls 160 when the oxidation is sensed, so that the reliability of the display device can be improved.

The pads PAD may include the first pad PAD1, the second pad PAD2, the third pad PAD3, the fourth pad PAD4, and the fifth pad PAD5. Each of the first and second pads PAD1 and PAD2 may electrically connect between the first conductive ball 161 and the first switch 131. The third pad PAD3 may electrically connect between the third conductive ball 163 and the pixels PX. Each of the fourth and fifth pads PAD4 and PAD5 may electrically connect between the second conductive ball 162 and second switch 132. The pads PAD may be components for inputting, to the inside of the display panel DP, signals (e.g., the first gate driver control signal SCS1, the second gate driver control signal SCS2, the first emission driver control signal ECS1, the second emission driver control signal ECS2, and the like) passing through the conductive balls 160.

The power supply 170 may transfer a first power voltage ELVDD and a second power voltage ELVSS to the pixels PX. The first power voltage ELVDD and the second power voltage ELVSS may be power voltages necessary for operations of the pixels PX. In embodiments, the first power voltage ELVDD may have a voltage level higher than a voltage level of the second power voltage ELVSS.

FIG. 2 is a schematic block diagram illustrating the driving integrated circuit shown in FIG. 1. FIG. 3 is a diagram illustrating an embodiment of the driving integrated circuit shown in FIG. 2.

Referring to FIGS. 1 to 3, the driving integrated circuit 150 may include input pads 151, a timing controller 152 (i.e., a timing controller circuit), a data driver 153, a waveform comparator 154 (i.e., a waveform comparator circuit), a control signal generator 155 (i.e., a control signal generator circuit), an output pad unit 156, and the like.

The input pads 151 may include a plurality of input pads (e.g., a 1ath input pad 151a, a 1bth input pad 151b, a 1cth input pad 151c, and the like).

The 1ath input pad 151a may receive input image data DATA1 and a control signal from an external device (e.g., a graphic processor, a set top box, or the like). The control signal may include a vertical synchronization signal Vsync, a horizontal synchronization signal, a data enable signal, a reference clock signal, and the like. The 1ath input pad 151a may be electrically connected to the timing controller 152. The 1ath input pad 151a may transfer the received input image data DATA1 and the received control signal to the timing controller 152.

The 1bth input pad 151b may receive an eleventh feedback signal FDS11 and a twenty-first feedback signal FDS21 from the first test pad 141. The 1bth input pad 151b may be electrically connected to the waveform comparator 154. The 1bth input pad 151b may transfer the received eleventh feedback signal FDS11 and the received twenty-first signal FDS21 to the waveform comparator 154. In an embodiment, the eleventh feedback signal FDS11 and the twenty-first signal FDS21 may be transferred from the first test pad 141 to the waveform comparator through the 1bth input pad 151b. The first test pad 141 may be electrically connected to the 1bth input pad 151b using wires.

The 1cth input pad 151c may receive a twelfth feedback signal FDS12 and a twenty-second feedback signal FDS22 from the second test pad 142. The 1cth input pad 151c may be electrically connected to the waveform comparator 154. The 1cth input pad 151c may transfer the received twelfth feedback signal FDS12 and the received twenty-second feedback signal FDS22 to the waveform comparator 154. In an embodiment, the twelfth feedback signal FDS12 and the twenty-second signal FDS22 may be transferred from the second test pad 142 to the waveform comparator 154 via the 1cth input pad 151c. The second test pad 142 may be electrically connected to the 1cth input pad 151c using wires.

The timing controller 152 may be electrically connected to the 1ath input pad 151a, and may receive the input image data DATA1 and the control signal, which are transferred from the 1ath input pad 151a. The timing controller 152 may generate a first gate driver control signal SCS1, a second gate driver control signal SCS2, a first emission driver control signal ECS1, and a second emission driver control signal ECS2, based on the control signal. The timing controller 152 may generate a data driver control signal DCS, based on the control signal. The timing controller 152 may generate image data DATA2 by converting the input image data DATA1. For example, the timing controller 152 may convert the input image data DATA1 into the image data DATA2 having a format corresponding to a pixel arrangement in the display panel DP.

The first gate driver control signal SCS1, the second gate driver control signal SCS2, the first emission driver control signal ECS1, and the second emission driver control signal ECS2 may include a start signal (or start pulse), clock signals, and the like.

The timing controller 152 may be electrically connected to the data driver 153. The timing controller 152 may transfer the data driver control signal DCS and the image data DATA2 to the data driver 153. The timing controller 152 may be electrically connected to the control signal generator 155. The timing controller 152 may transfer the first gate driver control signal SCS1, the second gate driver control signal SCS2, the first emission driver control signal ECS1, and the second emission driver control signal ECS2 to the control signal generator 155.

The data driver 153 may receive the data driver control signal DCS and the image data DATA2 from the timing controller 152, and generate data signals (or data voltages) corresponding to the image data DATA2. The data driver 153 may provide the generated data signals to the display panel DP through the output pad unit 156. For example, the data driver 153 may generate data signals corresponding to grayscale values in the image data, and supply the data signal to the data lines in units of pixel rows.

The data driver 153 may be mounted in the driving integrated circuit 150, be connected to the timing controller 152, and be connected to the data lines of the display panel DD through the output pad unit 156, the third conductive ball 163, and the third pad PAD3. In an embodiment, the third conductive ball 163 may connect the third pad PAD3 of the display panel Dd to the output pad unit 156 of the driving integrated circuit 150. In an embodiment, the output pad unit 156 may include a plurality of output pads.

In FIG. 2, it is illustrated that the timing controller 152 and the data driver 153 are integrated in the driving integrated circuit 150. However, the present disclosure is not limited thereto. For example, the timing controller 152 and the data driver 153 may be implemented as separated integrated circuits, which are on the same substrate to form a display driver device. When the display driver device is integrated into a single integrated circuit chip, it can be referred to as the driving integrated circuit 150.

The waveform comparator 154 may be electrically connected to the 1bth input pad 151b and the 1cth input pad 151c. The waveform comparator 154 may receive the eleventh feedback signal FDS11 and the twenty-first feedback signal FDS21, which are transferred from the 1bth input pad 151b. The waveform comparator 154 may receive the twelfth feedback signal FDS12 and the twenty-second feedback signal FDS22, which are transferred from the 1cth input pad 151c.

The waveform comparator 154 may be electrically connected to the control signal generator 155. The waveform comparator 154 may receive the first gate driver control signal SCS1, the second gate driver control signal SCS2, the first emission driver control signal ECS1, and the second emission driver control signal ECS2, which are transferred from the control signal generator 155.

The waveform comparator 154 may perform an operation of comparing, with each other, the signals transferred from the 1bth input pad 151b, the 1cth input pad 151c, and the control signal generator 155. For example, the waveform comparator 154 may compare a waveform of the first gate driver control signal SCS1 with a waveform of the eleventh feedback signal FDS11. For example, the waveform comparator 154 may compare a waveform of the first emission driver control signal ECS1 with a waveform of the twenty-first feedback signal FDS21. For example, the waveform comparator 154 may compare a waveform of the second gate driver control signal SCS2 with a waveform of the twelfth feedback signal FDS12. For example, the waveform comparator 154 may compare a waveform of the second emission driver control signal ECS2 with a waveform of the twenty-second feedback signal FDS22. Also, the waveform comparator 154 may transfer, to the control signal generator 155, a waveform comparison result obtained by comparing the waveforms of the signals. In an embodiment, the waveform comparator 154 may include a differential amplifier such as an operational amplifier. For example, the differential amplifier may receive the first gate driver control signal SCS1 and the eleventh feedback signal FDS11 through an inverting and non-inverting inputs, and may generate an output voltage proportional to the difference in voltage values of the first gate driver control signal SCS1 and the eleventh feedback signal FDS11. In an embodiment, the output voltage of the differential amplifier may be outputted to the control signal generator 155. This description can apply to waveform comparisons of other waveforms described above. The present disclosure is not limited thereto. In an embodiment, the waveform comparator may include a phase comparator circuit such as an XOR gate or a Phase-Locked Loop. For example, the phase comparator circuit may receive two waveforms and output a signal indicating a phase difference between the two waveforms.

The control signal generator 155 may be electrically connected to the waveform comparator 154, to receive the waveform comparison result transferred from the waveform comparator 154.

When the first conductive ball 161 is oxidized (or corroded), a difference may occur between the waveform of the first gate driver control signal SCS1 and the waveform of the eleventh feedback signal FDS11. The control signal generator 155 may sense oxidation (or corrosion) of the first conductive ball 161 through a waveform comparison result of the first gate driver control signal SCS1 and the eleventh feedback signal FDS11. For example, the control signal generator 155 may analyze the waveform comparison result of the first gate driver control signal SCS1 and the eleventh feedback signal FDS11 to determine whether the first conductive ball 161 is oxidized. The present disclosure is not limited thereto. In an embodiment, the control signal generator 155 may analyze the waveform comparison result of the first gate driver control signal SCS1 and the eleventh feedback signal FDS11 to determine whether the first conductive ball 161 is oxidized to the extent that the signal integrity of the first gate driver control signal SCS1 is affected.

When the first conductive ball 161 is oxidized (or corroded), a difference may occur between the waveform of the first emission driver control signal ECS1 and the waveform of the twenty-first feedback signal FDS21. The control signal generator 155 may sense oxidation (or corrosion) of the first conductive ball 161 through a waveform comparison result of the first emission driver control signal ECS1 and the twenty-first feedback signal FDS21.

When the second conductive ball 162 is oxidized (or corroded), a difference may occur between the waveform of the second gate driver control signal SCS2 and the waveform of the twelfth feedback signal FDS12. The control signal generator 155 may sense oxidation (or corrosion) of the second conductive ball 162 through a waveform comparison result of the second gate driver control signal SCS2 and the twelfth feedback signal FDS12.

When the second conductive ball 162 is oxidized (or corroded), a difference may occur between the waveform of the second emission driver control signal ECS2 and the waveform of the twenty-second feedback signal FDS22. The control signal generator 155 may sense oxidation (or corrosion) of the second conductive ball 162 through a waveform comparison result of the second emission driver control signal ECS2 and the twenty-second feedback signal FDS22.

When any oxidation (or corrosion) of the first and second conductive balls 161 and 162 is not sensed, the control signal generator 155 may supply (or output) the first gate driver control signal SCS1, the second gate driver control signal SCS2, the first emission driver control signal ECS1, and the second emission driver control signal ECS to the first and second conductive balls 161 and 162 through the output pad unit 156.

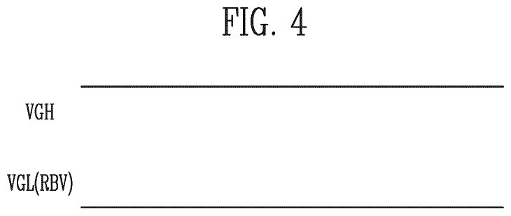

On the other hand, when oxidation (or corrosion) of the first conductive ball 161 and/or the second conductive ball 162 is sensed, the control signal generator 155 may output a reverse bias voltage RBV (see FIG. 4). The reverse bias voltage RBV may be transferred to the oxidized first conductive ball 161 and/or the oxidized second conductive ball 162 through the output pad unit 156. The reverse bias voltage RBV may be a voltage required to reduce the conductive balls 160. In an embodiment, the reverse bias voltage is a voltage level at which the first conductive ball is reduced (i.e., chemically reduced). The reverse bias voltage RBV may reduce the oxidized first conductive ball 161 and/or the oxidized second conductive ball 162. The reverse bias voltage RBV will be described later with reference to FIG. 4.

The control signal generator 155 may supply a first switch control signal SWCS1 (see FIG. 5) to the first switch 131, thereby turning on or turning off the first switch 131. Similarly, the control signal generator 155 may supply a second switch control signal SWCS2 (see FIG. 7) to the second switch 132, thereby turning on or turning off the second switch 132.

When the control signal generator 155 senses oxidation (or corrosion) of the first conductive ball 161, the control signal generator 155 may supply the first switch control signal SWCS1 for turning off the first switch 131 to the first switch 131, thereby turning off the first switch 131. Also, as described above, the control signal generator 155 may supply the reverse bias voltage RBV to the first conductive ball 161 through the output pad unit 156. Through this process, the first conductive ball 161 may be electrically reduced.

When the control signal generator 155 senses oxidation (or corrosion) of the second conductive ball 162, the control signal generator 155 may supply the second switch control signal SWCS2 for turning off the second switch 132 to the second switch 132, thereby turning off the second switch 132. Also, as described above, the control signal generator 155 may supply the reverse bias voltage RBV to the second conductive ball 162 through the output pad unit 156. Through this process, the second conductive ball 162 may be electrically reduced.

The output pad unit 156 may be electrically connected to the data driver 153 and the third conductive ball 163, and may receive data signals from the data driver 153 and transfer the data signals to the third conductive ball 163.

The output pad unit 156 may be electrically connected to the control signal generator 155 and the first conductive ball 161. The output pad unit 156 may receive signals (e.g., the first scan driver control signal SCS1 and the first emission driver control signal ECS) or the reverse bias voltage RBV from the control signal generator 155. Also, the output pad unit 156 may transfer the received signals or the received reverse bias voltage RBV to the first conductive ball 161.

The output pad unit 156 may be electrically connected to the control signal generator 155 and the second conductive ball 162. The output pad unit 156 may receive signals (e.g., the second scan driver control signal SCS2 and the second emission driver control signal ECS2) or the reverse bias voltage RBV from the control signal generator 155. Also, the output pad unit 156 may transfer the received signals or the received reverse bias voltage RBV to the second conductive ball 162.

FIG. 4 is a diagram illustrating the reverse bias voltage shown in FIG. 3.

Referring to FIG. 4, the first gate power voltage VGH may be a DC voltage having a positive level. The second gate voltage VGL may be a DC voltage having a negative level.

The reverse bias voltage RBV may be substantially the same as the second gate power voltage VGL. For example, the reverse bias voltage RBV may be a DC voltage having a negative level.

As described above with reference to FIG. 1, in a process of receiving signals from the driving integrated circuit 150, the conductive balls 160 may lose electrons due to a voltage component having a positive level, which is included in the signals. When such a phenomenon is repeated a few times, the conductive balls 160 may be oxidized (or corroded) or may be in electron-deficit state compared to a normal state (i.e., a neutral state). When the conductive balls 160 are in an electron-deficit state compared to the normal state, a portion of electrons in an input signal to the conductive balls 160 may charge the conductive balls (which corresponds to a reduction process), thereby distorting the shape of the waveform of the input signal passing through the conductive balls 160 or increasing a rising time of the input signal and degrading the signal integrity of the input signal. In a process of supplying the reverse bias voltage RBV (or the DC voltage having the negative level) to the oxidized conductive balls 160, electrons may be supplied to a portion which loses electrons. That is, electrons are supplied to the oxidized conductive balls 160, so that the oxidized conductive balls 160 can be reduced.

In accordance with the embodiments of the present disclosure, oxidation (or corrosion) of the conductive balls 160 is prevented, so that waveforms of signals output from the driving integrated circuit 150 can be prevented from being distorted due to the conductive balls 160. In addition, the driving integrated circuit 150 transfer signals of which waveforms are not distorted to the display panel DP, so that the reliability of the display device DD can be improved.

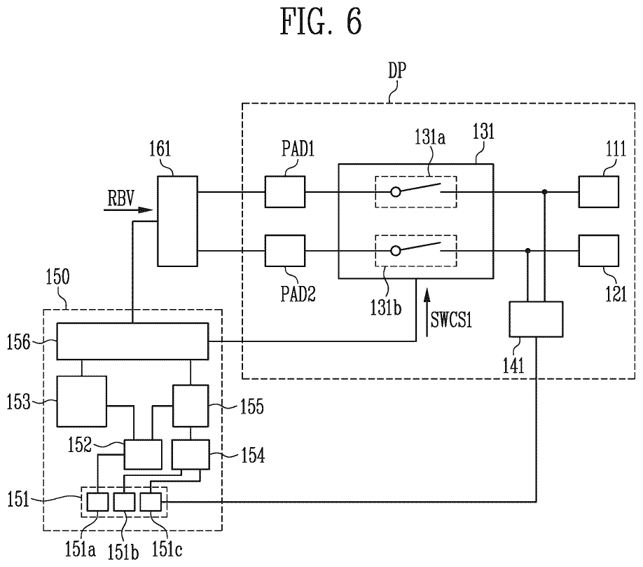

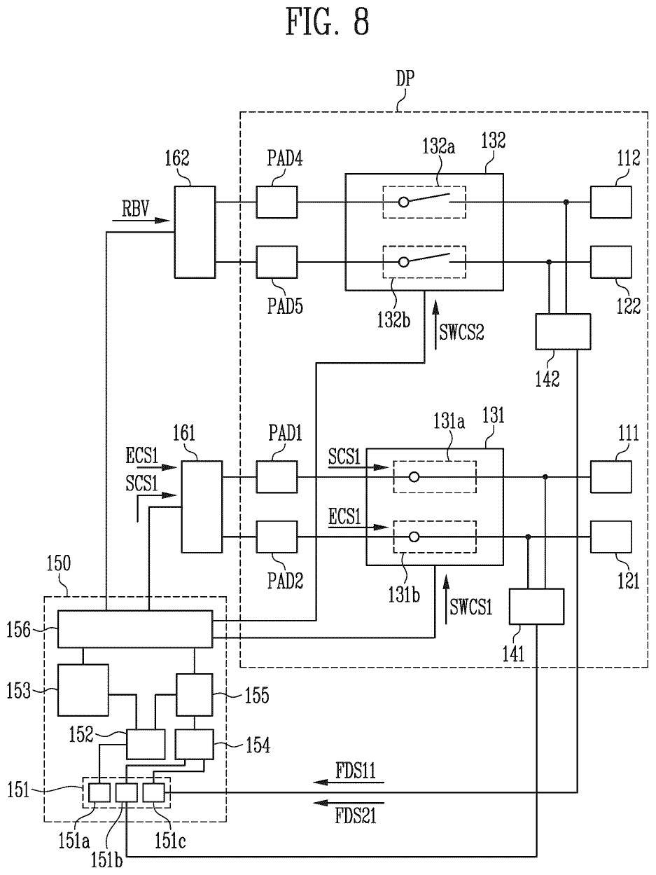

FIGS. 5 to 8 are schematic diagrams illustrating an embodiment of the display device shown in FIG. 1. FIG. 5 is a schematic diagram illustrating a case where any oxidation of the first conductive ball 161 is not sensed. FIG. 6 is a schematic diagram illustrating a case where oxidation of the first conductive ball 161 is sensed. FIGS. 7 and 8 are schematic diagrams illustrating a case where oxidation of each of the first conductive ball 161 and the second conductive ball 162 is sensed. An operation of the driving integrated circuit 150 according to whether oxidation of the second conductive ball 162 is sensed is substantially identical to an operation of the driving integrated circuit 150 according to whether oxidation of the first conductive ball 161 is sensed, and therefore, the first conductive ball 161 is described as an example in FIGS. 5 and 6.

Referring to FIG. 5, the driving integrated circuit 150 may supply the first gate driver control signal SCS1 and the emission driver control signal ECS1 to the first conductive ball 161.

The first conductive ball 161 may transfer the first gate driver control signal SCS1 to the first pad PAD1. The first conductive ball 161 may transfer the first emission driver control signal ECS1 to the second pad PAD2.

In FIG. 5, the driving integrated circuit 150 may supply the first switch control signal SWCS1 to the first switch 131, to turn on the first switch 131. When the first switch 131 is turned on, the 1ath switch 131a may connect the first pad PAD1 to the first gate driver 111. When the first switch 131 is turned on, the 1bth switch 131b may connect the second pad PAD2 to the first emission driver 121. In an embodiment, the 1ath switch 131a and the 1bth switch 131b may turn on simultaneously in response to the first switch control signal SWCS1. In an embodiment, the first switch control signal SWCS1 may include a plurality of switch control signals. Each of the 1ath switch 131a and the 1bth switch 131b may be independently controlled by a corresponding switch control signal of the plurality of switch control signals. The first pad PAD1 may transfer the first gate driver control signal SCS1 to the first gate driver 111 through the 1ath switch 131a. For example, the first gate driver control signal SCS1 may be transferred to the first gate driver 111 through the first pad PAD1 and the 1ath switch 131a. The second pad PAD2 may transfer the first emission driver control signal ECS1 to the first emission driver 121 through the 1bth switch 131b. For example, the first emission driver control signal ECS1 may be transferred to the first emission driver 121 through the second pad PAD2 and the 1bth switch 131b.

The first test pad 141 may detect the first gate driver control signal SCS1 transferred to the first gate driver 111. For example, the first test pad 141 may receive and transfer the first gate driver control signal SCS1 in the form of the eleventh feedback signal FDS11 to the driving integrated circuit 150. In other words, the first gate driver control signal SCS1 supplied from the driving integrated circuit 150 to the display panel DP may be return to the driving integrated circuit 150 through the first test pad 141.

Similarly, the first test pad 141 may detect the first emission driver control signal ECS1 transferred to the first emission driver 121. For example, the first test pad 141 may receive and transfer the first emission driver control signal ECS1 in the form of the twenty-first feedback signal FDS21 to the driving integrated circuit 150. In other words, the first emission driver control signal ECS1 supplied from the driving integrated circuit 150 to the display panel DP may be return to the driving integrated circuit 150 through the first test pad 141. In an embodiment, the returning of the first gate driver control signal SCS1 and the returning of the first emission driver control signal ESS1 may be performed separately by independently controlling the 1ath switch 131a and the 1bth switch 131b. For example, turning the 1ath switch 131a only may initiate the returning of the first gate driver control signal SCS1, and turning the 1bth switch 131b only may initiate the returning of the first emission driver control signal ECS1.

The driving integrated circuit 150 may compare the waveform of the first gate driver control signal SCS1 with the waveform of the eleventh feedback signal FDS11. Similarly, the driving integrated circuit 150 may compare the waveform of the first emission driver control signal ECS1 and the waveform of the twenty-first feedback signal FDS21. When waveforms of signals corresponding to each other are substantially the same (or when any oxidation of the first conductive ball 161 is not sensed), the above-described process may be repeated. On the other hand, an operation of the driving integrated circuit 150 when the waveforms of the signals are different from each other (or when oxidation of the first conductive ball 161 is sensed) will be described later with reference to FIG. 6.

Referring to FIG. 6, when oxidation of the first conductive ball 161 is sensed, the driving integrated circuit 150 may supply the first switch control signal SWCS1 to the first switch 131, thereby turning off the first switch 131. As the first switch 131 is turned off, the connection between the first pad PAD1 and the first gate driver 111 may be blocked, and the connection between the second pad PAD2 and the first emission driver 121 may be blocked.

Also, the driving integrated circuit 150 may supply the reverse bias voltage RBV to the first conductive ball 161. As the reverse bias voltage RBV is supplied to the first conductive ball 161, the oxidized first conductive ball 161 may be reduced (i.e., electrons may be supplied to fill the depleted electrons of the oxidized first conductive ball 161).

Referring to FIGS. 7 and 8, the driving integrated circuit 150 may sense oxidation of the first conductive ball 161 in a first period, and sense oxidation of the second conductive ball 162 in a second period different from the first period. When oxidation of each of the first conductive ball 161 and the second conductive ball 162 is sensed, an operation of reducing the first conductive ball 161 and an operation of reducing the second conductive ball 162 may be sequentially performed. A specific process is as follows.

First, as shown in FIG. 7, the driving integrated circuit 150 may supply the first switch control signal SWCS1 to the first switch 131, thereby turning off the first switch 131. The driving integrated circuit 150 may supply the second switch control signal SWCS2 to the second switch 132, thereby turning on the second switch 132. Accordingly, the connection of each of the first gate driver 111 and the first emission driver 121 with the driving integrated circuit 150 may be blocked. Each of the second gate driver 112 and the second emission driver 122 may be connected to the driving integrated circuit 150.

The driving integrated circuit 150 may supply the reverse bias voltage RBV to the first conductive ball 161, thereby reducing the first conductive ball 161. Also, in the same period, the driving integrated circuit 150 may supply the second gate driver control signal SCS2 and the second emission driver control signal ECS2 to the second conductive ball 162. Accordingly, the first conductive ball 161 may be reduced earlier than the second conductive ball 162.

Next, as shown in FIG. 8, the driving integrated circuit 150 may supply the first switch control signal SWCS1 to the first switch 131, thereby turning on the first switch 131. The driving integrated circuit 150 may supply the second switch control signal SWCS2 to the second switch 132, thereby turning off the second switch 132. Accordingly, each of the first gate driver 111 and the first emission driver 121 may be connected to the driving integrated circuit 150. The connection of each of the second gate driver 112 and the second emission driver 122 with the driving integrated circuit 150 may be blocked.

The driving integrated circuit 150 may supply the first gate driver control signal SCS1 and the first emission driver control signal ECS1 to the first conductive ball 161. Also, in the same period, the driving integrated circuit 150 may supply the revers bias voltage RBV to the second conductive ball 162. Accordingly, the second conductive ball 162 may be reduced.

As such, when the first conductive ball 161 and the second conductive ball 162 are oxidized (or corroded), the first conductive ball 161 and the second conductive ball 162 may be alternately reduced. However, embodiments of the present disclosure are not limited to as shown in FIGS. 7 and 8. For example, the second conductive ball 162 may be reduced earlier than the first conductive ball 161.

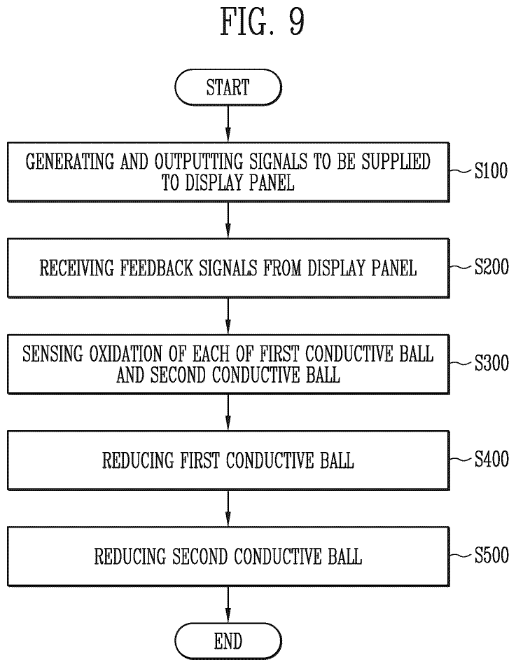

FIG. 9 is a flowchart illustrating a method of driving the display device shown in FIG. 1.

Referring to FIGS. 1 to 9, first, the driving integrated circuit 150 may perform step S100 of generating and outputting signals (e.g., the first gate driver control signal SCS1, the second gate driver control signal SCS2, the first emission driver control signal ECS1, the second emission driver control signal ECS2, and the like) to be supplied to the display panel DP.

The driving integrated circuit 150 may perform step S200 of receiving, from the display panel DP, feedback signals (e.g., the eleventh feedback signal FDS11, the twelfth feedback signal FDS12, the twenty-first feedback signal FDS21, and the twenty-second feedback signal FDS22).

The driving integrated circuit 150 may perform step S300 of sensing oxidation of each of the first conductive ball 161 and the second conductive ball 162. For example, the driving integrated circuit 150 may sense oxidation of the first conductive ball 161 by comparing the waveform of the first gate driver control signal SCS1 and the waveform of the eleventh feedback signal FDS11. For example, the driving integrated circuit 150 may sense oxidation of the second conductive ball 162 by comparing the waveform of the second gate driver control signal SCS2 and the waveform of the twelfth feedback signal FDS12.

The driving integrated circuit 150 may perform step S400 of reducing the first conductive ball 161 when the first conductive ball 161 is oxidized. The driving integrated circuit 150 may turn off the first switch 131, and supply the reverse bias voltage RBV to the first conductive ball 161.

The driving integrated circuit 150 may perform step S500 of reducing the second conductive ball 162 when the second conductive ball 162 is oxidized. The driving integrated circuit 150 may turn off the second switch 132, and supply the reverse bias voltage RBV to the second conductive ball 162.

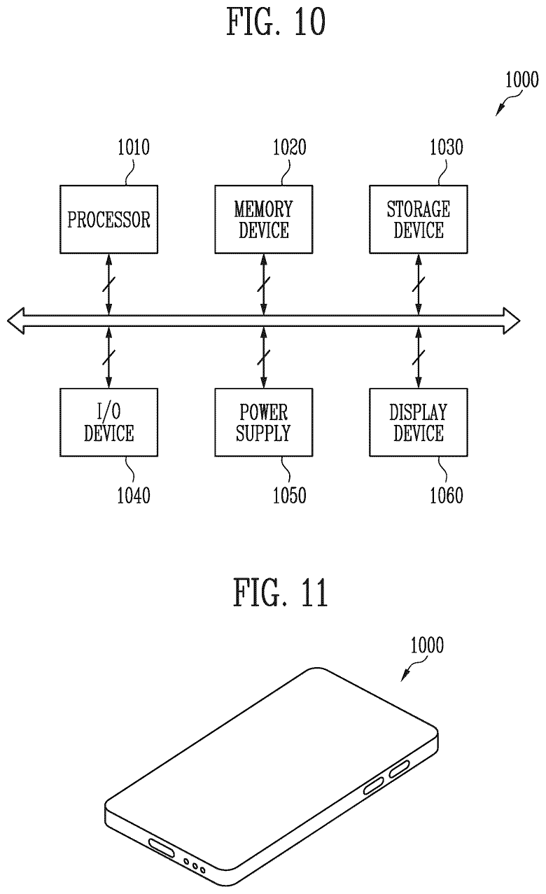

FIG. 10 is a block diagram illustrating an electronic device in accordance with embodiments of the present disclosure. FIG. 11 is a diagram illustrating an example in which the electronic device shown in FIG. 10 is implemented as a smartphone.

Referring to FIGS. 10 and 11, an electronic device 1000 may include a processor 1010, a memory device 1020, a storage device 1030, an input/output (I/O) device 1040, a power supply, 1050, and a display device 1060. The display device 1060 may be the display device shown in FIG. 1. Also, the electronic device 1000 may further include several ports capable of communicating with a video card, a sound card, a memory card, a USB device, and the like, or communicating with other systems. In an embodiment, as shown in FIG. 10, the electronic device 1000 may be implemented as a smartphone. However, this is merely illustrative, and the electronic device 1000 is not limited thereto. For example, the electronic device 1000 may be implemented as a mobile phone, a video phone, a smart pad, a smart watch, a tablet PC, a vehicle navigation system, a computer monitor, a notebook computer, a head mounted display device, or the like.

The processor 1010 may perform specific calculations or tasks. In some embodiments, the processor 1010 may be a microprocessor, a central processing unit, an application processor, or the like. The processor 1010 may be connected to other components through an address bus, a control bus, a data bus, and the like. In some embodiments, the processor 1010 may be connected to an extension bus such as a peripheral component interconnect (PCI) bus.

The memory device 1020 may store data necessary for an operation of the electronic device 1000. For example, the memory device 1020 may include a nonvolatile memory device such as an Erasable Programmable Read-Only Memory (EPROM) device, an Electrically Erasable Programmable Read-Only Memory (EEPROM) device, a flash memory device, a Phase Change Random Access Memory (PRAM) device, a Resistance Random Access Memory (RRAM) device, a Nano Floating Gate Memory (NFGM) device, a Polymer Random Access Memory (PORAM) device, a Magnetic Random Access Memory (MRAM) device, or a Ferroelectric Random Access Memory (FRAM) device, and/or a volatile memory device such as a Dynamic Random Access Memory (DRAM) device, a Static Random Access Memory (SRAM) device, or a mobile DRAM device.

The storage device 1030 may include a Solid State Drive (SSD), a Hard Disk Drive (HDD), a CD-ROM, and the like.

The I/O device 1040 may include an input means such as a keyboard, a keypad, a touch screen, or a mouse, and an output means such as a speaker or a printer. In some embodiments, the display device 1060 may be included in the I/O device 1040.

The power supply 1050 may supply power necessary for an operation of the electronic device 1000. For example, the power supply 1050 may be a power management integrated circuit (PMIC).

The display device 1060 may display an image corresponding to visual information of the electronic device 1000. The display device 1060 may be an organic light emitting display device or a quantum dot light emitting display device, but the present disclosure is not limited thereto. The display device 1060 may be connected to other components through the buses or another communication link.

In accordance with the present disclosure, oxidation of conductive balls is minimized, thereby improving the reliability of the display device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A display device comprising:
a display panel including a plurality of pixels;
a first conductive ball connected to the display panel; and
a driving integrated circuit connected to the first conductive ball and configured to:
generate and output a first gate driver control signal to the display panel through the first conductive ball,
receive a first return signal of the first gate driver control signal from the display panel, wherein the first return signal corresponds to the first gate drive control signal provided to the display panel through the first conductive ball, and
perform a first waveform comparing operation in which a waveform of the first gate driver control signal is compared with a waveform of the first return signal to determine whether the first conductive ball is oxidized.

2. The display device of claim 1,
wherein the display panel includes:
a first gate driver configured to supply a plurality of first gate signals to corresponding first pixels of the plurality of pixels;
a first panel input pad connected to the first conductive ball and receiving the first gate driver control signal from the driving integrated circuit through the first conductive ball;
a first switch selectively connecting the first panel input pad to the first gate driver in response to a first switch control signal of the driving integrated circuit; and
a first test pad connected to an output of the first switch and the driving integrated circuit, wherein the first return signal is transferred to the driving integrated circuit through the first test pad.

3. The display device of claim 2, further comprising:
a second conductive ball electrically connecting the driving integrated circuit to the display panel,
wherein the driving integrated circuit is configured further to:
generate and output a second gate driver control signal to the display panel through the second conductive ball, and
receive a second return signal of the second gate driver control signal from the display panel, wherein the second return signal corresponds to the second gate drive control signal provided to the display panel through the second conductive ball,
perform a second waveform comparing operation in which a waveform of the second gate driver control signal is compared with a waveform of the second return signal to determine whether the second conductive ball is oxidized.

4. The display device of claim 3,
wherein the display panel further includes:
a second gate driver spaced apart from the first gate driver in a first direction, the second gate driver supplying a plurality of second gate signals of the plurality of gate signals to corresponding second pixels of the plurality of pixels;
a second panel input pad receiving the second gate driver control signal from the driving integrated circuit through the second conductive ball;
a second switch selectively connecting the second panel input pad to the second gate driver in response to a second switch control signal of the driving integrated circuit; and
a second test pad connected to an output of the second switch and the driving integrated circuit, wherein the second return signal is transferred to the driving integrated circuit through the second test pad.

5. The display device of claim 3,
wherein the driving integrated circuit is configured to perform the first waveform comparing operation and the second waveform comparing operation in a first period and in a second period, respectively, and
wherein the first period is different from the first period.

6. The display device of claim 3,
wherein the first gate driver control signal and the second gate driver control signal are substantially the same.

7. The display device of claim 3,
wherein the driving integrated circuit includes:
a timing controller circuit configured to generate the first gate driver control signal;
a first return input pad connected to the first test pad of the display panel and receiving the first return signal from the first test pad of the display panel; and
a waveform comparator circuit configured to compare the waveform of the first gate driver control signal with the waveform of the first return signal, and compare the waveform of the second gate driver control signal with the waveform of the second return signal.

8. The display device of claim 7,
wherein the driving integrated circuit further includes:
a control signal generator circuit configured to:
receive a waveform comparison result transferred from the waveform comparator circuit;
determine whether the first conductive ball is oxidized based on the waveform comparison result; and
in response to determination of the first conductive ball being oxidized, turn off the first switch and supply a reverse bias voltage to the first conductive ball.

9. The display device of claim 8,
wherein the driving integrated circuit further includes an output pad unit including a plurality of output pads,
wherein the output pad unit is connected to the control signal generator circuit, the first conductive ball, and the first switch, and
wherein the control signal generator circuit is configured to supply the first switch control signal to the first switch through a corresponding output pad of the output pad unit.

10. The display device of claim 8,
wherein the reverse bias voltage is a voltage level at which the first conductive ball is reduced.

11. A method of driving a display device including a display panel and a first conductive ball electrically connected to the display panel, the method comprising:
generating and outputting a first gate driver control signal to the display panel through the first conductive ball;
receiving a first return signal of the first gate driver control signal from the display panel, wherein the first return signal corresponds to the first gate drive control signal provided to the display panel through the first conductive ball; and
performing a first waveform comparing operation in which a waveform of the first gate driver control signal is compared with a waveform of the first return signal to determine whether the first conductive ball is oxidized.

12. The method of claim 11,
wherein the receiving of the first return signal of the first gate driver control signal from the display panel includes transferring the first return signal to a driving integrated circuit through a first switch and a first test pad of the display panel.

13. The method of claim 12,
wherein the display device further includes a second conductive ball electrically connected to the display panel, and
wherein the method further comprises:
generating and outputting a second gate driver control signal to the display panel through the second conductive ball, and
receiving a second return signal of the second gate driver control signal from the display panel, wherein the second return signal corresponds to the second gate drive control signal provided to the display panel through the second conductive ball,
performing a second waveform comparing operation in which a waveform of the second gate driver control signal is compared with a waveform of the second return signal to determine whether the second conductive ball is oxidized.

14. The method of claim 13,
wherein the receiving of the second return signal of the second gate driver control signal from the display panel includes transferring the second return signal to the driving integrated circuit through a second switch and a second test pad of the display panel.

15. The method of claim 13,
wherein the first gate driver control signal and the second gate driver control signal are substantially the same.

16. The method of claim 14, further comprising:
reducing the first conductive ball at a first period; and
reducing the second conductive ball at a second period different from the first period.

17. The method of claim 16,
wherein the reducing of the first conductive ball includes:
determining whether the first conductive ball is oxidized based on a waveform comparison result of the performing of the first waveform comparing operation; and
in response to determination of the first conductive ball being oxidized, turning off the first switch and supplying a first revers bias voltage to the first conductive ball so that the first conductive ball is reduced in the first period, and wherein the reducing of the second conductive ball includes
determining whether the second conductive ball is oxidized based on a waveform comparison result of the performing of the second waveform comparing operation; and
in response to determination of the second conductive ball being oxidized, turning off the second switch and supplying a second revers bias voltage to the second conductive ball so that the second conductive ball is reduced in the second period.

18. The method of claim 17,
wherein the first reverse bias voltage is a voltage level at which the first conductive ball is reduced, and
wherein the first reverse bias voltage and the second reverse bias voltage have the same voltage level.

19. A display device comprising:
a display panel including a plurality of pixels;
a first conductive ball connected to the display panel; and
a display driving device connected to the first conductive ball and configured to:
supply a first gate driver control signal to the display panel through the first conductive ball,
receive a first return signal of the first gate driver control signal from the display panel, wherein the first return signal corresponds to the first gate drive control signal provided to the display panel through the first conductive ball,
perform a first waveform comparing operation in which a waveform of the first gate driver control signal is compared with a waveform of the first return signal,
determine whether the first conductive ball is oxidized based on a waveform comparison result of the first waveform comparing operation, and
supply a revers bias voltage to the first conductive ball in response to the determination of the first conductive ball is oxidized.

20. The display device of claim 19,
wherein the reverse bias voltage is a voltage level at which the first conductive ball is reduced.
